(19) United States
(12) Patent Application Publication
(10) Pub. No.: US 2026/0165156 A1
(43) Pub. Date: Jun. 11, 2026

(54) PACKAGE-ON-PACKAGE DEVICE WITH REDISTRIBUTION DIE

(71) Applicant: QUALCOMM Incorporated, San Diego, CA (US)

(72) Inventors: Aniket PATIL, San Diego, CA (US); Manuel ALDRETE, Encinitas, CA (US); Bohan YAN, San Diego, CA (US)

(21) Appl. No.: 18/971,142

(22) Filed: Dec. 6, 2024

(51) Int. Cl. H01L 23/538; H01L 23/00; H01L 23/373; H01L 25/00; H01L 25/18

(52) U.S. Cl. CPC H10W 70/611; H10W 70/65; H10W 90/00; H10W 90/401; H10W 40/258; H10W 90/724

(57) ABSTRACT

A device includes a first substrate that includes a first set of contacts. The device also includes a redistribution die coupled to first contacts of the first set of contacts and to second contacts of the first set of contacts. The redistribution die includes conductors that electrically couple the first contacts of the first set of contacts to the second contacts of the first set of contacts. The device also includes a first integrated device coupled to third contacts of the first set of contacts. The device also includes a second integrated device coupled to a second substrate. The first substrate is disposed between the first integrated device and the second integrated device, and the first integrated device is electrically coupled to the second integrated device through the conductors of the redistribution die.

### FIELD

Various features relate to integrated circuit devices.

### BACKGROUND

In the context of integrated circuit (IC) packaging, a “packaged IC device” (or simply a “package”) refers to an arrangement of one or more IC devices with additional components that facilitate operation of the IC devices. For example, the additional components retain and protect the IC devices. The additional components often electrically connect the IC devices to one another and include off-package contact to enable the packaged IC device to be connected to other circuits or devices. The IC devices and components coupled together in a package can be configured to perform various electrical functions.

There is an ongoing demand for improved packages. For example, many package improvements focus on goals such as reducing the dimensions of the package, increasing the performance of the package or the IC devices therein, increasing the efficiency of the package or the IC devices, reducing the cost of the package or the IC devices therein, or combinations of the above. Unfortunately, it is often the case that improvements to one of these goals comes at the cost of one or more of the others. For example, reducing package size can exacerbate heat dissipation concerns, which can necessitate performance throttling to limit heat generation.

### SUMMARY

Various features relate to integrated circuit (IC) devices.

One example provides a device that includes a first substrate that includes a first set of contacts. The device also includes a redistribution die coupled to first contacts of the first set of contacts and to second contacts of the first set of contacts. The redistribution die includes conductors that electrically couple the first contacts of the first set of contacts to the second contacts of the first set of contacts. The device also includes a first integrated device coupled to third contacts of the first set of contacts. The device further includes a second integrated device coupled to a second substrate. The first substrate is disposed between the first integrated device and the second integrated device, and the first integrated device is electrically coupled to the second integrated device through the conductors of the redistribution die.

Another example provides a device that includes a first substrate that includes a first set of contacts and a second set of contacts. The device also includes a first redistribution die coupled to first contacts of the first set of contacts and to second contacts of the first set of contacts. The first redistribution die includes conductors that electrically couple the first contacts of the first set of contacts to the second contacts of the first set of contacts. The device also includes a second redistribution die coupled to first contacts of the second set of contacts and to second contacts of the second set of contacts. The second redistribution die includes conductors that electrically couple the first contacts of the second set of contacts to the second contacts of the second set of contacts. The device also includes a first dynamic random access memory (DRAM) device coupled to third contacts of the first set of contacts and to third contacts of the second set of contacts. The device also includes a system-on-chip (SOC) device coupled to a second substrate. The first substrate is disposed between the first DRAM device and the SOC device, and the first DRAM device is electrically coupled to the SOC device through the conductors of the first redistribution die and the second redistribution die.

Another example provides a method of fabricating an integrated device that includes coupling a redistribution die to a first substrate that includes a first set of contacts. Coupling the redistribution die to the first substrate includes electrically coupling first contacts of the redistribution die to first contacts of the first set of contacts, and electrically coupling second contacts of the redistribution die to second contacts of the first set of contacts. The method also includes coupling a first integrated device to third contacts of the first set of contacts to define one or more signal paths that electrically couple the first integrated device to a second integrated device through conductors of the redistribution die that electrically couple the second contacts of the first set of contacts to the third contacts of the first set of contacts.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1A illustrates a schematic top view of an exemplary device including one or more redistribution dies.

FIG. 1B illustrates a schematic cross-sectional profile view of the exemplary device of FIG. 1A.

FIG. 1C illustrates another schematic cross-sectional profile view of the exemplary device of FIG. 1A.

FIG. 2 illustrates a schematic cross-sectional profile view of another exemplary device including redistribution dies.

FIG. 3 illustrates a schematic top view of another exemplary device including redistribution dies and a second device that does not include redistribution dies.

FIG. 4 illustrates a schematic top view of another exemplary device including redistribution dies.

FIG. 5 illustrates a schematic top view of another exemplary device including redistribution dies.

FIGS. 6A and 6B illustrate an exemplary sequence for fabricating a device including one or more redistribution dies.

FIG. 7 illustrates an exemplary flow diagram of a method for fabricating a device including one or more redistribution dies.

FIG. 8 illustrates various electronic devices that may integrate a device including one or more redistribution dies as described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

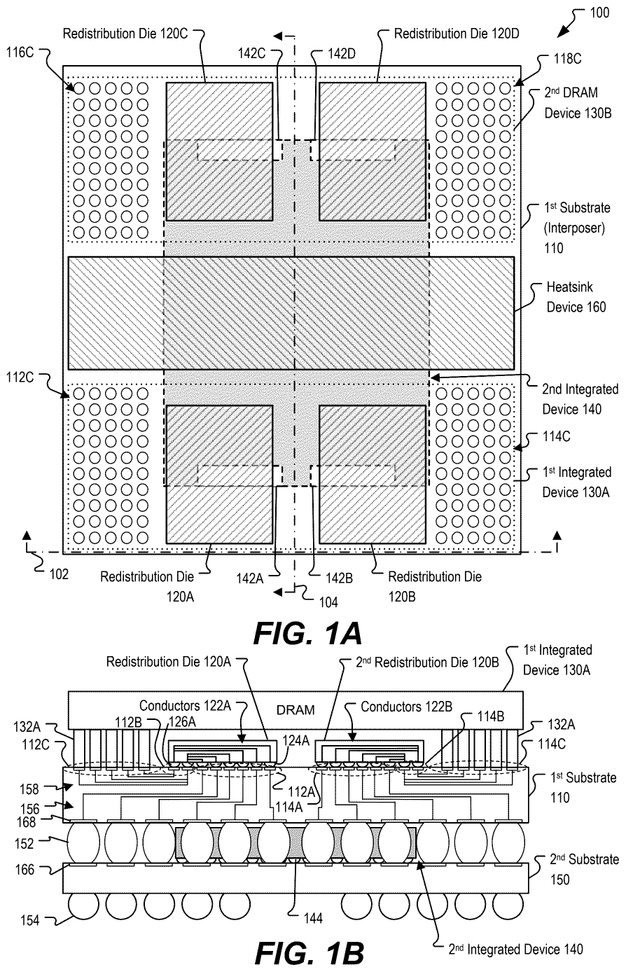

Particular aspects of the present disclosure are described below with reference to the drawings. In the description, common features are designated by common reference numbers. In some drawings, multiple instances of a particular type of feature are used. Although these features are physically and/or logically distinct, the same reference number is used for each, and the different instances are distinguished by addition of a letter to the reference number. When the features as a group or a type are referred to herein (e.g., when no particular one of the features is being referenced), the reference number is used without a distinguishing letter. However, when one particular feature of multiple features of the same type is referred to herein, the reference number is used with the distinguishing letter. For example, referring to FIG. 1, multiple redistribution dies are illustrated and associated with reference numbers 120A, 120B, 120C, and 120D. When referring to a particular one of these redistribution dies, such as a redistribution die 120A, the distinguishing letter “A” is used. However, when referring to any arbitrary one of these redistribution dies or to these redistribution dies as a group, the reference number 120 is used without a distinguishing letter.

As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demand for lower cost and more capable electronic devices has led to increasing complexity of ICs. Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middleof-line (MOL) interconnect layers, which interconnect to the FEOL active devices of an IC. As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Improvements in technology and increased demand, among other things, are driving performance improvements in integrated circuits. Such performance improvements are often accompanied by increases in the number of I/O connections of newer integrated circuits. At the same time, there is increasing demand for smaller IC packages. However, increasing performance of individual components within a package tends to increase the amount of heat generated by the components, while reducing the package size and/or increasing the density of the components in the package typically hinders the ability to conduct heat away from internal components of the package. When a threshold amount of heat has built up within a package, such as due to a heavy processing workload at a high-performance system-on-chip (SOC) device in the interior of the package, operation of the SOC and/or other devices in the package may have to be throttled until the package has sufficiently cooled to resume normal operation. As a result, overall device performance can suffer.

As a particular example, conventional memory packages that include a four-channel dynamic random access memory (DRAM) die stacked above a SOC die can exhibit reduced performance due to relatively low thermal conductivity for dissipating the heat that is generated by the SOC, which is encased in the package under the DRAM die. One approach to improve memory package performance is to use a split-DRAM stack configuration in which a heat slug (e.g., a block of thermally conductive material) is positioned above the SOC to enhance heat dissipation away from the SOC, and a pair of 2-channel DRAM devices are positioned on either side of the heat slug. Although this split-DRAM approach results in improved performance, such as a 3-4% improved benchmark performance as compared to the conventional memory packages, the performance improvement of this approach is limited by the routing complexity for conveying signals for each of the four DRAM channels from the corresponding physical memory interfaces of the SOC on the lower stack layer to the respective DRAM devices on the upper stack layer.

To illustrate, thermal performance of the split-DRAM configuration could be further improved by rotating the orientation of the DRAM devices by 90 degrees, which would allow the DRAM devices to be spaced farther apart, so that a larger heat slug could be used for more effective heat transfer from the SOC. However, simply rotating the orientation of the DRAM devices significantly increases the complexity of routing the signal paths between the SOC and the DRAM devices. One potential solution is to increase the footprint of the device and add additional conductive layers to one or more substrates in the device to accommodate the increased routing complexity arising from the need to disentangle the signal paths of the DRAM channels; however, device footprint and height criteria can prevent such enlarging of the device size. Another potential solution is to redesign the floorplan of the SOC to reposition the physical memory interfaces (e.g., double data rate (DDR) components) to more closely align with the DDR pinmap of the rotated DRAM devices and therefore reduce the routing complexity; however, redesigning the SOC introduces substantial cost and requires different versions of the SOC to be maintained for the different types of memory packages.

Aspects disclosed herein relate to improvements to IC packages to increase the amount of routing complexity that can be accommodated as compared to conventional Package-on-Package (PoP) devices. In PoP devices, two or more substrates are stacked. Each substrate can be attached to one or more die, and signaling (e.g., I/O) between a die (e.g., a SOC) on a bottom substrate and a device (e.g., a DRAM) on the top substrate (e.g., an interposer) is routed through a set of interconnect conductors that are electrically connected to both substrates. According to the disclosed techniques, one or more redistribution dies are coupled to the top substrate to enable higher routing complexity for conveying signals between the stack layers.

A redistribution die refers to a component, such as a die, that facilitates electrical connection or electrical signaling between other components, such as other dies. For example, the redistribution die facilitates electrical connection between one component and another component where the one and another components have contacts or pads with different spacing and/or orientation and/or size. The redistribution die provides contacts that match the components to facilitate electrical connection, without modifying electrical characteristics of signals sent therebetween. The redistribution die includes passive interconnects (referred to herein as “conductors” or “redistribution traces”) defining conductive pathways between pairs of externally facing contacts of the redistribution die such that each pair of the externally facing contacts is configured to enable signal routing between two other components that are electrically connected to the redistribution die.

In one embodiment the redistribution die's primary function is to operate to facilitate electrical connections. In another embodiment the redistribution die may perform other die functions in addition to redistribution functions.

The redistribution die can be manufactured using semiconductor fabrication techniques, which are able to form more densely packed traces, of higher quality, than can be manufactured using substrate manufacturing techniques. By using narrower, more closely spaced traces, the redistribution die can perform redistribution routing on the top substrate in less area (or volume) of the top substrate than would be needed to provide similar routing in the conductive layers of the top substrate. Thus, the redistribution die enables increased signal routing at the top substrate without a corresponding increase in the footprint or thickness of the top substrate. According to an aspect, the one or more redistribution dies are at least partially in the shadow, e.g., within a ball stand-off area, of a device attached to the top substate.

As a particular example, one or more redistribution dies can be positioned within the shadow of each DRAM device of a split-DRAM package and configured to disentangle signal paths between the SOC and the DRAMs, thus enabling the 90-degree rotated orientation of the DRAM devices described above to be implemented without increasing the package size and also without redesigning the floorplan of the SOC. The rotated orientation of the DRAM devices enables a larger heat slug to be attached to the top substrate between the DRAM devices, resulting in improved thermal performance.

In addition to more efficient use of PoP substrate area, using redistribution dies rather than substrate-based connections can provide shorter signal paths between the dies of the top and bottom substrates. Shorter signal paths improve communication speeds between the dies. Further, the long, fine traces used in conventional laminate substrates for signal routing can suffer from poor signal integrity and are generally correlated with lower fabrication yield. Using the redistribution die(s) disclosed herein enables use of shorter traces in the substrate, which should improve substrate yield and signal integrity.

Thus, technical benefits of various implementations disclosed herein relative to conventional PoP packaging techniques include at least, more efficient use of package area, which enables a higher complexity of connections (e.g., between dies in the same size or a smaller size package), reduction in the package size, or both. Further technical benefits include improved connections speeds, higher signal integrity, better thermal performance, and improved yield.

### Exemplary Device Including Redistribution Die(s)

FIG. 1A illustrates a schematic top view of aspects of an exemplary device 100 that includes one or more redistribution dies 120 (including a first redistribution die 120A, a second redistribution die 120B, a third redistribution die 120C, and a fourth redistribution die 120D). In particular, FIG. 1A illustrates a top view of a first substrate 110 of the device 100 and indicates positions of the redistribution die(s) 120, one or more first integrated device(s) 130 (e.g., a first DRAM device 130A and a second DRAM device 130B) and a heatsink device 160 mounted on a top surface of the first substrate 110. FIG. 1A also shows a position of a second integrated device 140, which is coupled to a second substrate 150 and is beneath the first substrate 110. FIG. 1B illustrates a schematic cross-sectional profile view of the exemplary device 100 according to a first viewing plane line 102 depicted in FIG. 1A, and FIG. 1C illustrates a schematic cross-sectional profile view of the exemplary device 100 according to a second viewing plane line 104 depicted in FIG. 1A.

The device 100 has a package-on-package (PoP) configuration in which the second integrated device 140 is disposed between the second substrate 150 and the first substrate 110, and the first integrated device(s) 130 are mounted to the top surface of the first substrate 110. The PoP configuration is configured to enable signaling between the first integrated device(s) 130 and the second integrated device 140, signaling between one or more of the first integrated device(s) 130 or the second integrated device 140 and one or more off-package devices (e.g., via off-package contacts 154, such as a ball grid array), or both. While two first integrated device(s) 130 and the second integrated device 140 are illustrated, the device 100 can optionally include other devices (not shown), such as passive devices.

Each of the first integrated device(s) 130 and the second integrated device 140 can include integrated circuitry, such as a plurality of transistors and/or other circuit elements. Components of the integrated circuitry can be formed in and/or over a semiconductor substrate. Different implementations can use different types of transistors to form active circuitry, such as a field effect transistor (FET), planar FET, finFET, a gate all around FET, or mixtures of transistor types. The active circuitry can be arranged and interconnected to form processing logic blocks (e.g., transistor blocks), memory blocks, etc. In addition to active circuitry, the integrated circuitry can also include a power distribution network (PDN). To illustrate, a PDN can include, for example, one or more power rails, one or more ground rails, etc. In some implementations, a front end of line (FEOL) process may be used to fabricate the integrated circuitry in and/or over the semiconductor substrate.

According to an aspect, the second integrated device 140 has a flip-chip configuration including, as shown in FIG. 1C, a set of contacts 144 (e.g., flip-chip bumps) that are electrically connected to integrated circuitry of the second integrated device 140 and configured to couple to corresponding contacts 164 of the second substrate 150. In a particular embodiment, the second integrated device 140 includes a SOC device having one or more double data rate (DDR) components 142 configured to provide a physical interface for one or more DRAM channels. As illustrated in FIG. 1A, the DDR component(s) 142 include a DDR component 142A (e.g., low-power DDR (LPDDR) channel 0), a DDR component 142B (e.g., LPDDR channel 2), a DDR component 142C (e.g., LPDDR channel 1), and a DDR component 142D (e.g., LPDDR channel 3).

The second substrate 150 also includes conductors 162 (shown in FIG. 1C) electrically connected to respective ones of the contacts 164 and electrically connected to contacts 166 of the second substrate 150. The contacts 166 are configured to be electrically connected to corresponding interconnect conductors 152 (e.g., core solder balls), which are electrically coupled to respective contacts 168 on a bottom surface of the first substrate 110.

The first substrate 110 can correspond to an interposer and is disposed between the first integrated device(s) 130 and the second integrated device 140. The bottom surface of the first substrate 110 includes the contacts 168, and the top surface of the first substrate 110 includes a first set of contacts 112, a second set of contacts 114, a third set of contacts 116, and a fourth set of contacts 118.

As illustrated in FIG. 1B, the first set of contacts 112 include first contacts 112A, second contacts 112B, and third contacts 112C. The first contacts 112A are electrically coupled to conductors 156 of the first substrate 110, which are electrically coupled to respective contacts 168. The second contacts 112B are electrically coupled to conductors 158 of the first substrate 110, which are electrically coupled to respective third contacts 112C. According to an aspect, the third contacts 112C correspond to ball pads and are coupled to respective interconnect conductors 132A (e.g., solder balls) of the first DRAM device 130A.

The first redistribution die 120A includes contacts 124A that are configured to be electrically coupled to the first contacts 112A and contacts 126A that are configured to be electrically coupled to the second contacts 112B. The first redistribution die 120A also includes conductors 122A that are coupled to the contacts 124A and to the contacts 126A and that electrically connect each of the contacts 124A to a corresponding one of the contacts 124B. The conductors 122A thus enable the first redistribution die 120A to electrically couple the first contacts 112A to the second contacts 112B. The conductors 122A are configured to disentangle the electrical signal paths from various ones of the contacts 144 of the second integrated device 140 to appropriate interconnect conductors 132A. To illustrate, a signal path from the second integrated device 140 to the first DRAM device 130A can include a contact 144 of the second integrated device 140; a contact 164, a conductor 162, and a contact 166 of the second substrate 150; an interconnect conductor 152; a contact 168, a conductor 156, and a first contact 112A of the first substrate 110; a contact 124A, a conductor 122A, and a contact 126A of the first redistribution die 120A; a second contact 112B, a conductor 158, and a third contact 112C of the first substrate 110; and an interconnect conductor 132A.

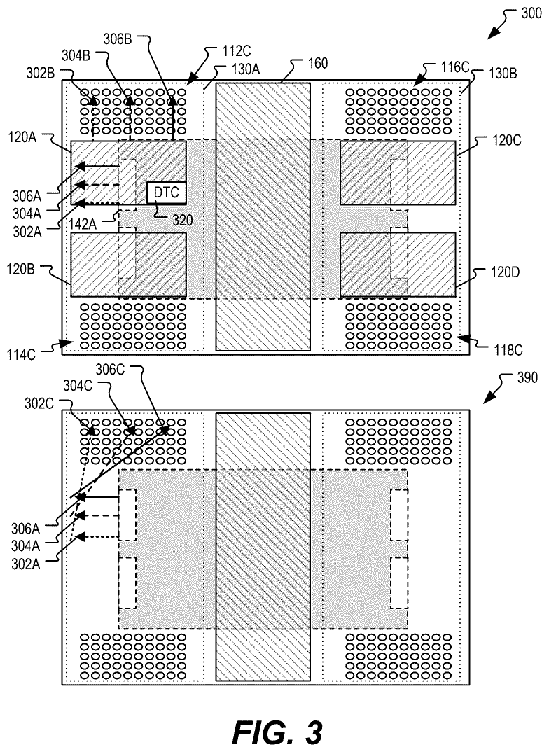

The conductors 122A of the first redistribution die 120A can be arranged in two or more layers of the redistribution die 120 such that two or more of the conductors 122A can hop over/under one another to route between individual contacts 168 on the bottom surface of the first substrate 110 and respective third contacts 112C on the top surface of the first substrate 110. The redistribution die(s) 120 can include semiconductor die(s) in which the conductors 122A are integrated using semiconductor fabrication techniques (e.g., wafer-level patterning and deposition). As a result, the conductors 122A can be finer (e.g., narrower) and more closely spaced than the conductors 158 (which are formed, for example, using lamination techniques). The finer, more closely spaced lines of the conductors 122A enables the conductors 122A to disentangle the electrical connections between contacts 144 of the second integrated device 140 and the interconnect conductors 132A in a smaller volume than would be required to perform the same disentanglement using the conductors 158 of the first substrate 110, as described in further detail with reference to FIG. 3. For example, routing each of the DDR signal paths between the DDR component 142A of the second integrated device 140 and the first DRAM device 130A without using the first redistribution die 120A would require the first substrate 110 to have additional layers to provide sufficient routing area for conductors in the first substrate 110 to electrically connect pairs of the interconnect conductors 152 and the interconnect conductors 132A. Also, signal routing through the first redistribution die 120A results in higher quality signals and, according to some aspects, improved thermal performance, as compared to using only conductors in the first substrate 110.

The first substrate 110 also includes the second set of contacts 114 that are positioned and interconnected to operate in a similar manner as described for the first set of contacts 112. To illustrate, the second set of contacts 114 include first contacts 114A (shown in FIG. 1B), second contacts 114B, and third contacts 114C. The first contacts 114A and the second contacts 114B are configured to be coupled to the redistribution die 120B. The first contacts 114A are also coupled to conductors 156 that provide electrical coupling to respective contacts 168. The second contacts 114B and the third contacts 114C are connected by conductors 158 of the first substrate 110, and the third contacts 114C (e.g., ball pads) are configured to be coupled to interconnect conductors 132A of the first DRAM device 130A.

The second redistribution die 120B is coupled to the first contacts 114A and to the second contacts 114B and configured to route signal paths between the second integrated device 140 and the first DRAM device 130A in a similar manner as described for the first redistribution die 120A. As illustrated, the second redistribution die 120B includes conductors 122B that electrically couple the first contacts 114A to the second contacts 114B.

The first DRAM device 130A is coupled to the third contacts 112C of the first set of contacts 112 and to the third contacts 114C of the second set of contacts 114. According to an aspect, the interconnect conductors 132A of the first DRAM device 130A correspond to solder balls, the third contacts 112C and the third contacts 114C correspond to ball pads, and the first DRAM device 130A is mounted on the first substrate 110 such that the interconnect conductors 132A are in contact with respective contacts of the third contacts 112C and the third contacts 114C.

The second DRAM device 130B is coupled to third contacts 116C of the third set of contacts 116 and to third contacts 118C of the fourth set of contacts 118. According to an aspect, the interconnect conductors 132B of the second DRAM device 130B correspond to solder balls, the third contacts 116C and the third contacts 118C correspond to ball pads, and the second DRAM device 130B is mounted on the first substrate 110 such that the interconnect conductors 132B (shown in FIG. 1C) are in contact with respective contacts of the third contacts 116C and the third contacts 118C.

Routing of signal paths between the second integrated device 140 and the second DRAM device 130B is performed using the third redistribution die 120C and the fourth redistribution die 120D in a similar manner as described for the first redistribution die 120A and the second redistribution die 120B. To illustrate, referring to FIG. 1C, the third redistribution die 120C includes contacts 124C that are coupled to first contacts 116A of the third set of contacts 116 and includes contacts 126C that are coupled to second contacts 116B of the third set of contacts 116. The third redistribution die 120C includes conductors (not shown) that interconnect contacts 124C to contacts 126C to electrically couple the first contacts 116A to the second contacts 116B in an analogous manner as described with reference to the conductors 122A of the first redistribution die 120A. Conductors 158 in the first substrate 110 electrically couple the second contacts 116B to the third contacts 116C (which are coupled to interconnect conductors 132B of the second DRAM device 130B), and conductors 156 in the first substrate 110 electrically couple the first contacts 116A to contacts 168 on the bottom of the first substrate 110 (which are coupled to the DDR component 142C of the second integrated device 140 via interconnect conductors 152 and conductors 162 in the second substrate 150).

Similarly, the fourth redistribution die 120D is coupled to first contacts (not shown) of the fourth set of contacts 118 and to second contacts (not shown) of the fourth set of contacts 118, and includes conductors (not shown) that electrically couple the first contacts of the fourth set of contacts 118 to the second contacts of the fourth set of contacts 118 in an analogous manner as described with reference to the first contacts 112A, the second contacts 112B, and the conductors 122A of the first redistribution die 120A. Conductors 158 in the first substrate 110 electrically couple the second contacts of the fourth set of contacts 118 to the third contacts 118C of the fourth set of contacts 118 (which are coupled to the interconnect conductors 132B of the second DRAM device 130B), and conductors 156 in the first substrate 110 electrically couple the first contacts of the fourth set of contacts 118 to contacts 168 on the bottom of the first substrate 110 (which are coupled to the DDR component 142D of the second integrated device 140 via interconnect conductors 152 and conductors 162 in the second substrate 150).

In some implementations, each of the redistribution dies 120 is associated with a different communication channel between the second integrated device 140 and the DRAM devices 130A, 130B. For example, the first DRAM device 130A and the second DRAM device 130B can each include or correspond to a two-channel DDR memory, in which case each of the four redistribution dies 120 may be configured to route signals associated with a corresponding one of the four channels.

According to an aspect, each of the first redistribution die 120A and the second redistribution die 120B are at least partially disposed within a shadow of the first DRAM device 130A. To illustrate, the first redistribution die 120A and the second redistribution die 120B are beneath the first DRAM device 130A and above the first substrate 110, in the ball standoff space of the first DRAM device 130A. In addition, the first redistribution die 120A and the second redistribution die 120B are between the third contacts 112C and the third contacts 114C, which can correspond to ball pads that are arranged according to a Joint Electron Device Engineering Council (JEDEC) DRAM pinmap. Similarly, each of the third redistribution die 120C and the fourth redistribution die 120D are at least partially disposed within a shadow of the second DRAM device 130B, in the ball standoff space of the second DRAM device 130B and between the third contacts 116C and the third contacts 118C. As a result, the redistribution dies 120 can be included in the device 100 without requiring a horizontal or vertical size increase of the device 100 to accommodate the redistribution dies 120.

According to an aspect, the first DRAM device 130A and the second DRAM device 130B are in a side-by-side configuration on the first substrate 110, and the heatsink device 160 is coupled to the first substrate 110 and positioned between the first DRAM device 130A and the second DRAM device 130B. The heatsink device 160 includes a thermally conductive material, such as copper, to transfer heat generated by the second integrated device 140. Because the high-density interconnects provided by the redistribution dies 120 enable routing of signals between the DDR components 142 on the short edges of the second integrated device 140 (e.g., having a north-south orientation in FIG. 1A) to respective ones of the third contacts 112C, 114C, 116C, 118C, that are proximate to the long edges of the second integrated device 140, the DRAM devices 130A, 130B can be mounted having the east-west orientation illustrated in FIG. 1A. As a result, a larger spacing is available between the DRAM devices 130A, 130B as compared to another split-DRAM configuration in which routing limitations of the first substrate 110 restrict the DRAM devices to having the north-south orientation (to reduce routing complexity by positioning the DRAM solder balls proximate to and in alignment with the respective DDR components 142).

The resulting larger spacing between the DRAM devices 130A, 130B enables a larger heatsink device 160 to be used to cool the second integrated device 140, improving the thermal efficiency of the device 100 and thus improving performance of the second integrated device 140 and the device 100 overall. For example, because enhanced routing provided by the redistribution dies 120 enables the DRAM devices 130A, 130B to have the east-west orientation and thus enables use of a larger heatsink device 160, heat conduction away from the second integrated device 140 is improved. As a result, temperature-related throttling of the second integrated device 140 can be reduced or eliminated, resulting in improved average performance of the second integrated device 140. In an illustrative, non-limiting example, a split-DRAM configuration (e.g., with DRAMs having the north-south orientation and a smaller heatsink device) provides a 3.7% CPU performance benchmark improvement as compared to a conventional non-split DRAM configuration, while the device 100 (e.g., with DRAMs having the east-west orientation and the larger heatsink device 160) exhibits a 5.3% performance benchmark improvement.

Use of the redistribution dies 120 to provide high-density interconnections enables more complex signal routing between the second integrated device 140 and the DRAM devices 130A, 130B than would be possible without increasing the footprint of the first substrate 110, increasing the number of layers and thus the height of the first substrate 110, or both. As a result, a package size can be minimized while maintaining enhanced routing complexity, (e.g., enabling confined routing of DDR signals on the first substrate 110 due to the redistribution dies 120 functioning as high density interconnect patches under the DRAM devices 130A, 130B). Further, using a high interconnect density substrate (e.g., silicon for the redistribution dies 120) provides improved signal quality, improved thermal performance, or both, as compared to solely using interconnects in the first substrate 110.

Another technical advantage is that the more complex signal routing provided by the redistribution dies 120 enables signal routing between the DDR components 142 on the north and south edges of the second integrated device 140 and the DRAM devices 130A, 130B in the east-west orientation of FIG. 1A, which enables use of a larger heatsink device 160 as compared to another configuration in which the redistribution dies 120 are omitted and the DRAM devices 130A, 130B are limited to having the north-south orientation. Use of the larger heatsink device 160 provides a thermal performance boost by reducing heat accumulation and therefore reducing (or eliminating) throttling of the second integrated device 140.

Use of the redistribution dies 120 enables multiple possible package configurations that may be compatible with one or more JEDEC DRAM pinmap, one or more custom DRAM pinmap, or any combination thereof and can enable a universal package solution to provide a pin to pin compatible package. According to an aspect, a single package substrate design can be used for multiple DRAM solutions, such as for LP6 and LP5, LP6 JEDEC and any other custom type, or any combination thereof.

Optionally, one or more of the redistribution dies 120 includes one or more other components in addition to the contacts and the conductors described above. For example, the first redistribution die 120A can include one or more deep trench capacitors coupled to a power distribution network of the first DRAM device 130A through one or more of the third contacts 112C for improved PDN performance, such as described in further detail with reference to FIG. 3.

The device 100 can optionally include a mold compound disposed between the second substrate 150 and the first substrate 110, between the first substrate 110 and the first integrated device(s) 130, or a combination thereof. For example, the mold compound can at least partially encapsulate the second integrated device 140, the interconnect conductors 152, or a combination thereof. For example, the interconnect conductors 152 can include through mold vias or solder balls disposed within the mold compound. As another example, the mold compound can at least partially encapsulate the second redistribution die(s) 120, the interconnect conductors 132, or a combination thereof, and the interconnect conductors 132 can include through mold vias or solder balls disposed within the mold compound.

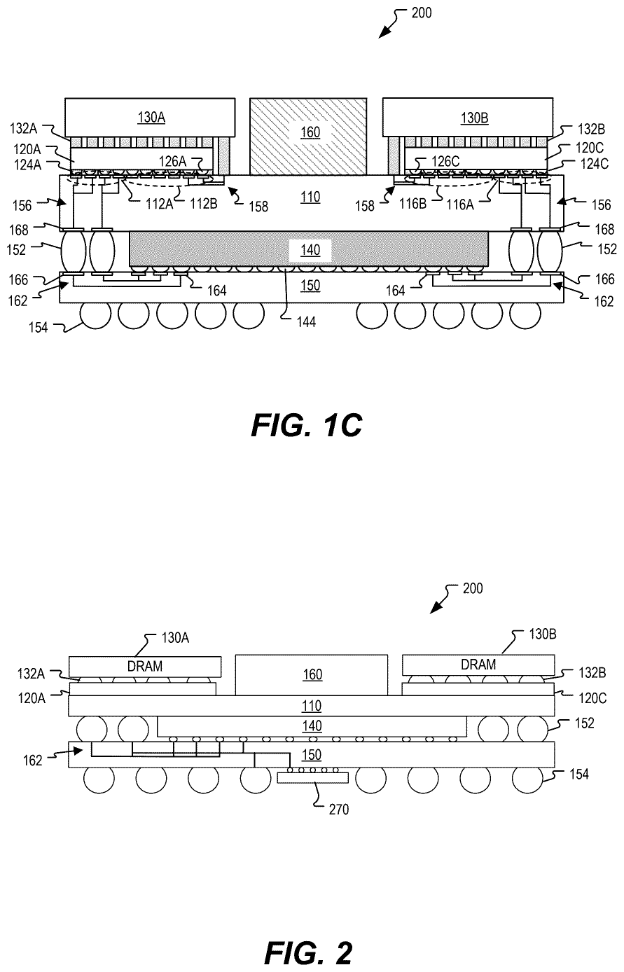

FIG. 2 illustrates aspects of another exemplary device 200 that includes the redistribution dies 120 and also includes one or more additional devices 270, such as a die that includes one or more passive components. In particular, FIG. 2 illustrates a schematic cross-sectional profile view of the exemplary device 200 having a same orientation as depicted in FIG. 1C.

The device 200 of FIG. 2 corresponds to the device 100 of FIGS. 1A-1C except that in the case of the device 200, an additional device 270 is coupled to a bottom surface of the second substrate 150, and the conductors 162 of the second substrate 150 are configured to electrically couple the device 270 to the second integrated device 140, to one or more of the interconnect conductors 132A, 132B, or a combination thereof. As an illustrative, non-limiting example, one or more components within the device 270 (e.g., one or more deep trench capacitors, as an illustrative, non-limiting example) can be coupled to the first DRAM device 130A (e.g., a power distribution network and/or active circuitry of the first DRAM device 130A) via signal path(s) that pass through the interconnect conductors 152 and that are routed within the first redistribution die 120A to respective interconnect conductor(s) 132A of the first DRAM device 130A.

A technical advantage of using one or more of the redistribution dies 120 to route interconnections to one or more additional devices 270 is flexibility of placement of the one or more additional devices 270 to locations that would not otherwise be possible if interconnect routing were performed solely via conductors in the first substrate 110. As illustrated, the one or more additional devices 270 can be placed within the ball standoff space of the second substrate 150 without requiring an increase in the size (e.g., footprint and/or height) of the device 200.

FIG. 3 illustrates aspects of an exemplary device 300 that includes the redistribution dies 120, and a second device 390 that omits the redistribution dies 120. In particular, FIG. 3 illustrates a schematic top view of the exemplary device 300 and the second device 390.

The device 300 of FIG. 3 corresponds to the device 100 of FIGS. 1A-1C except that in the case of the device 300, an optional additional component 320, such as a passive component (e.g., a deep trench capacitor (DTC)), is included in the first redistribution die 120A. For example, the first redistribution die 120A can include a deep trench capacitor that is coupled to a power distribution network and/or other components of the first DRAM device 130A via interconnections between first redistribution die 120A and the interconnect conductors 132A, including through one or more of the third contacts 112C.

Three sets of signal paths 302, 304, and 306 illustrate signal communication, via the first redistribution die 120A, between the DDR component 142A and the first DRAM device 130A. According to an aspect, the signal paths 302, 304, 306 carry signals corresponding to a first data subchannel (e.g., DQ0), a command/address subchannel (e.g., C/A), and a second data subchannel (e.g.., DQ1), respectively, of the LPDDR channel 0. A first portion 302A of the signal path 302, a first portion 304A of the signal path 304, and a first portion 306A of the signal path 306 are illustrated as relative straight paths, along conductors 162 of the second substrate 150 to respective interconnect conductors 152. The signal paths 302, 304, and 306 continue vertically along the interconnect conductors 152 to the conductors 156 in the first substrate 110 and into the first redistribution die 120A via the first contacts 112A of the first substrate 110 and respective contacts 124A of the first redistribution die 120A.

Each of the signal paths 302, 304, and 306 is routed the conductors 122A in the first redistribution die 120A to appropriate contacts of the second contacts 112B on the top surface of the first substrate 110, from which the signal paths 302, 304, and 306 extend along conductors 158 in the first substrate 110 to respective contacts of the third contacts 112C. As illustrated, a second portion 302B of the signal path 302, a second portion 304B of the signal path 304, and a second portion 306B of the signal path 306 are illustrated as relatively straight paths, along the conductors 158 of the second substrate 150 to respective third contacts 112C. Because the first redistribution die 120A enables high-density, complex routing of the signal paths 302, 304, and 306, the resulting second portions 302B, 304B, and 306B of the signal paths through the conductors 158 in the first substrate 110 can be relatively straightforward, without having to cross over each other and without (or with very few) 90-degree turns.

In contrast, in the second device 392, second portions 302C, 304C, and 306C of the signal paths 302, 304, and 306, respectively, are entangled and have to cross over each other and follow complex routes along the conductors in the first substrate 110 to reach their respective destinations among the third contacts 112C. As a result, the first substrate 110 in the second device 392 may be required to have a larger floorplan, more layers and thus larger height, or both, to accomplish the routing, as compared to the first device 300.

In embodiments in which the optional additional component(s) 320 are included in the first redistribution die 120A, any complex routing between the first DRAM device 130A and the component(s) 320 can be performed in the conductors 122A of the first redistribution die 120A instead of in the conductors of the first substrate 110, in a similar manner as described for the signal paths 302, 304, and 306. Including the optional component 320, such as one or more capacitors for the power distribution network of the first DRAM device 130A, in the first redistribution die 120A, provides the technical advantages of reducing distance and parasitic effects between the component 320 and the power distribution network thus improving performance of the power distribution network, along with the advantages associated with reduced routing complexity, e.g., to a device mounted beneath the first substrate 110 and/or the second substrate 150 as discussed previously.

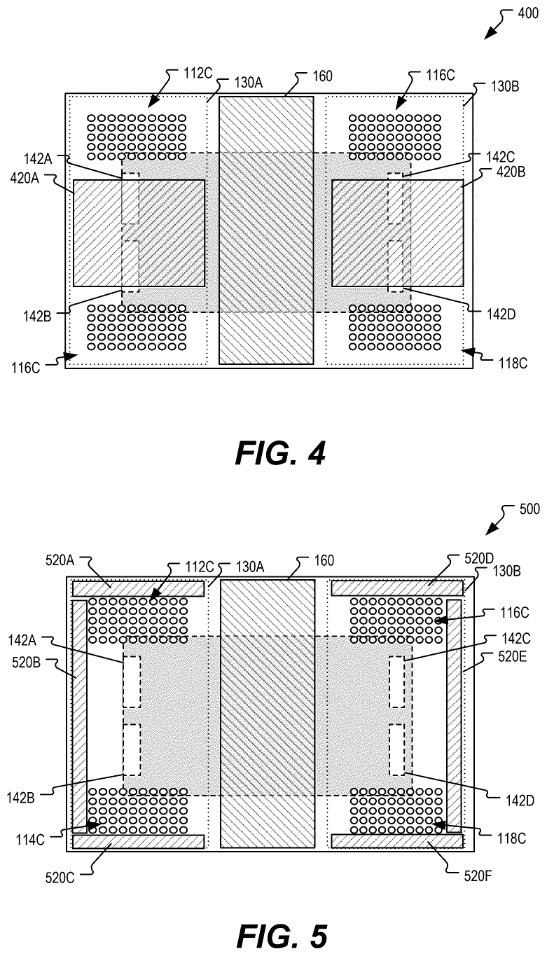

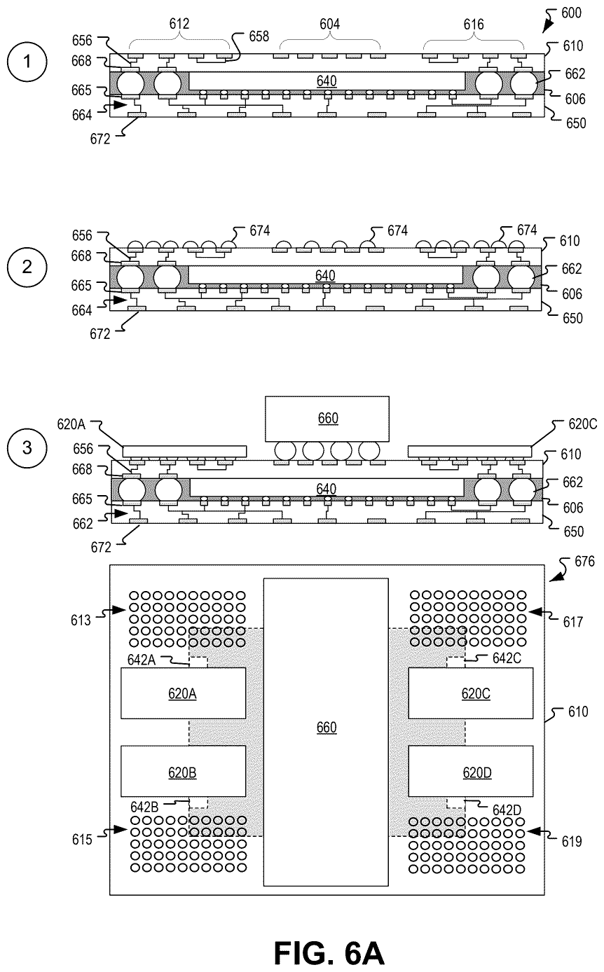

Although the embodiments illustrated in FIGS. 1A-1C, FIG. 2, and device 300 FIG. 3 each includes four redistribution dies 120 positioned at least partially in the ball standoff space under the respective first integrated devices 130 and between the sets of contacts 112C and 114C or between the sets of contacts 116C and 118C, other implementations may use different numbers and/or arrangements of redistribution dies 120, as depicted in the illustrative, non-limiting examples of FIG. 4 and FIG. 5.

FIG. 4 illustrates aspects of an exemplary device 400 that includes two redistribution dies 420. In particular, FIG. 4 illustrates a schematic top view of the exemplary device 400.

The device 400 of FIG. 4 corresponds to the device 100 of FIGS. 1A-1C except that the device 400 includes two redistribution dies 420, as compared to the four redistribution dies 120 illustrated in FIG. 1A. For example, a first redistribution die 420A can be configured to perform the routing that is performed by both the first redistribution die 120A and the second redistribution die 120B of FIG. 1. In an illustrative implementation, the first redistribution die 420A includes internal conductors to route signal paths between the DDR component 142A and the third contacts 112C, and between the DDR component 142B and the third contacts 116C. Similarly, a second redistribution die 420B can include internal conductors to route signal paths between the DDR component 142C and the third contacts 116C, and between the DDR component 142D and the third contacts 118C.

FIG. 5 illustrates aspects of an exemplary device 500 that includes six redistribution dies 520. In particular, FIG. 5 illustrates a schematic top view of the exemplary device 500.

The device 500 of FIG. 5 corresponds to the device 100 of FIGS. 1A-1C except that the device 500 includes six redistribution dies 520, as compared to the four redistribution dies 120 illustrated in FIG. 1A, and the conductors in the first substrate 110 are adjusted to provide signal paths between the contacts 168 on the bottom surface of the first substrate 110, the redistribution dies 520, and the sets of contacts 112C, 114C, 116C, and 118C on the top surface of the first substrate 110. For example, a first redistribution die 520A, a second redistribution die 520B, and a third redistribution die 520C can be configured to perform the routing that is performed by both the first redistribution die 120A and the second redistribution die 120B of FIG. 1 and can each include internal conductors that are configured such that the redistribution dies 520A, 520B, and 520C, individually or as a group, route signal paths between the DDR component 142A and the third contacts 112C, and between the DDR component 142B and the third contacts 116C.

Similarly, a fourth redistribution die 520D, a fifth redistribution die 520E, and a sixth redistribution die 520F can be configured to perform, as a group, the routing that is performed by both the third redistribution die 120C and the fourth redistribution die 120D of FIG. 1. Each of the redistribution dies 520D, 520E, and 520F include internal conductors that are configured such that the redistribution dies 520D, 520E, and 520F, individually or as a group, route signal paths between the DDR component 142C and the third contacts 116C, and between the DDR component 142D and the third contacts 118C.

As illustrated, the redistribution dies 520 are arranged along a periphery of the first substrate 110 and at least partially in the shadow of the DRAM devices 130A, 130B in the ball standoff space. The redistribution dies 520 thus enable connectivity of rotated DRAM pins relative to PHY pins (e.g., due to the orientation of the DRAM devices 130A, 130B being rotated relative to the orientation of the DDR components 142) without requiring an increase of the footprint or number of layers of the first substrate 110 to accommodate the signal routing, in a similar manner as described for the device 100 of FIGS. 1A-1C.

The diagrams illustrated in FIGS. 1A-5 are merely schematic, and are intended to highlight particular features of the various devices illustrated. For example, the specific number of contacts, interconnections, and other components is merely illustrative, and not limiting. Further, certain internal structures have been omitted from the diagrams. For example, the first substrate 110 or the second substrate 150 can include additional conductors that are configured to electrically connect the first integrated device(s) 130, the second integrated device 140, or both, to off-package devices via the interconnect conductors 132, the interconnect conductors 152, the off-package contacts 154, or any combination thereof. Further, certain components are illustrated in a particular manner merely to illustrate a particular aspect. For example, connections between the contacts 124A, 124B of the redistribution die 120A and corresponding contacts 112A, 112B of the first substrate 110 are illustrated as formed using solder bumps merely to highlight where separate components of an electric connection are positioned. In other implementations, other interconnection techniques are used to electrically connect the various contacts.

While FIGS. 1A-5 illustrate examples of devices that include connections for two first integrated devices 130 (e.g., DRAM devices) and one second integrated device 140 (e.g., a SOC die), in other examples, a device can include different numbers and/or types of integrated devices and/or dies. For example, a device can include a single first integrated device 130 or more than two first integrated devices 130, instead of the two integrated devices 130 illustrated in FIG. 1A-5. Further, the devices 100, 200, 300, 400, 500 of FIGS. 1A-5 can be integrated with or included within a wide variety of other devices. For example, a device that includes one or more of the devices 100, 200, 300, 400, 500 disclosed herein can include components such as a power management integrated circuit (PMIC), an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. In such devices, the device(s) disclosed herein can operate as any of these components (or a combination of these components) that includes active circuitry.

### Exemplary Sequence for Fabricating a Device Including Redistribution Die(s)

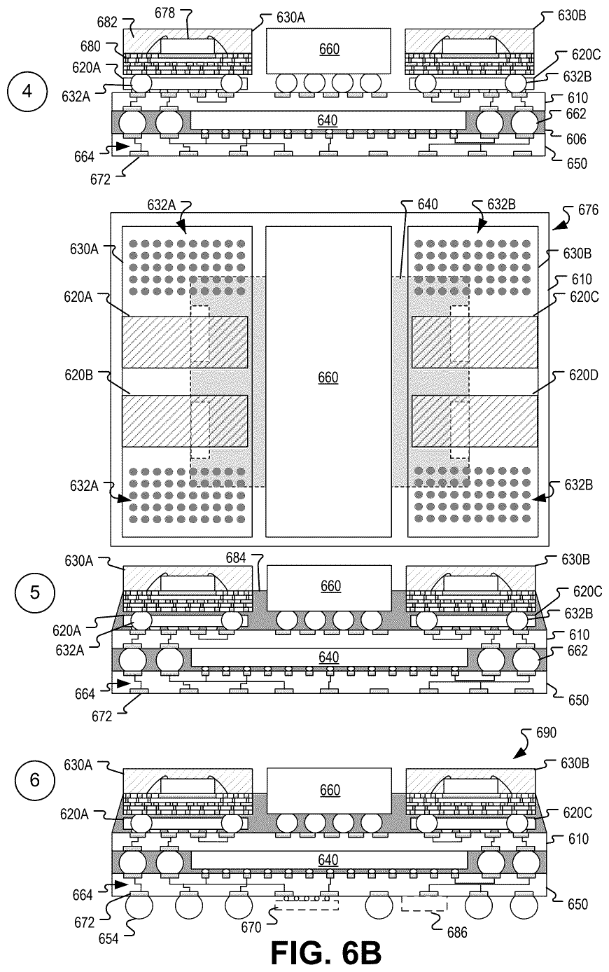

In some implementations, fabricating a device that includes one or more redistribution dies (e.g., any of the devices 100, 200, 300, 400, or 500) includes several processes. FIGS. 6A and 6B illustrate an exemplary sequence for providing or fabricating a device (e.g., device 690 illustrated at Stage 6 of FIG. 6B) that includes one or more redistribution dies, as described with reference to any of FIGS. 1A-5. In some implementations, the sequence of FIGS. 6A and 6B may be used to provide (e.g., during fabrication of) one or more of the devices 100, 200, 300, 400, or 500 of FIGS. 1A-5.

It should be noted that the sequence of FIGS. 6A and 6B may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 6A and 6B. Each of the various stages of the sequence illustrated in FIGS. 6A and 6B shows one device being formed; however, in some implementations, multiple devices are formed concurrently, e.g., using wafer-level or strip-level processing techniques.

Stage 1 of FIG. 6A illustrates a state after formation of an assembly 600. The assembly 600 includes an integrated device 640 disposed between two substrates, including a substrate 650 and a substrate 610. The integrated device 640 corresponds to an example or instance of the second integrated device 140 of FIGS. 1A-1C.

The substrate 650 in FIG. 6A includes the features of the second substrate 150 of FIGS. 1A-1C. The substrate 650 includes multiple metal layers separated from one another by one or more dielectric layers and patterned to form contacts, traces, pads, etc. and interconnected by vias. In particular, the substrate 650 includes contacts 665 for interconnect conductors 662 and for the integrated device 640 on a first (e.g., top) side of the substrate 650. The substrate 650 also includes contacts 672 on a second (e.g., bottom) side of the substrate 650. Routing traces 664 in the substrate 650 interconnect pairs of contacts 665 (e.g., to electrically couple contacts of the integrated device 640 to the interconnect conductors 662) and interconnect one or more of the contacts 665 to the contacts 672. In a particular implementation, the routing traces 664 correspond to an example of the conductors 162 of FIG. 1C or FIG. 2. The second side of the substrate 650 can also include a solder resist layer (not shown) or another protective layer or passivation layer through which various pads and/or contacts (e.g., off-package contacts 672) can be accessed.

Likewise, the substrate 610 includes the features of the first substrate 110 of FIGS. 1A-1C. The substrate 610 includes multiple metal layers separated from one another by one or more dielectric layers and patterned to form contacts, traces, pads, etc. and interconnected by vias. In particular, the substrate 610 includes contacts 612 for a first set of one or more redistribution dies 620 (shown at Stage 3) and one or more integrated devices 630 (shown at Stage 4 of FIG. 6B), contacts 616 for a second set of one or more redistribution dies 620 and one or more integrated devices 630, and one or more contacts 604 for one or more heat slugs 660 (shown at Stage 3) on a first (e.g., top) surface of the substrate 610. The substrate 610 also includes contacts 668 for interconnect conductors 662 on a second (e.g., bottom) side of the substrate 610. In some implementations, the contacts 612 correspond to the first set of contacts 112, the contacts 616 correspond to the third set of contacts 116, and the contacts 668 correspond to the contacts 168 of FIGS. 1A-1C. In a particular implementation, the contacts 604 are thermally coupled (through one or more vias in the substrate 610) to one or more contacts on the second side of the substrate 610 adjacent to the integrated device 640, which may contact a thermal interface material disposed between the substrate 610 and the integrated device 640.

In the example illustrated in FIG. 6A, the substrate 610 also includes one or more routing traces 658 between one or more pairs of adjacent contacts 612 and also between one or more pairs of adjacent contacts 616. The routing traces 658 provide interconnections between contacts 612 that connect to a redistribution die (e.g. the redistribution die 620A of Stage 3) and contacts 613 (e.g., a subset of the contacts 612, shown in Stage 3) that connect to an integrated device 630 (shown in Stage 4 of FIG. 6B). In some implementations, the routing traces 658 correspond to examples of the conductors 158 of FIGS. 1A-1C. The substrate 610 also includes one or more routing traces 656 between the contacts 668 on the second side of the substrate 610 and one or more of the contacts 612 and the contacts 616 on the first side of the substrate 610. In some implementations, the routing traces 656 correspond to examples of the conductors 156 of FIGS. 1A-1C. The first side of the substrate 610 can also include a solder resist layer (not shown) or another protective layer or passivation layer through which various pads and/or contacts can be accessed.

Each of the substrates 610, 650 can be formed using various lamination and patterning techniques. To illustrate, one or both of the substrates 610, 650 can be pre-formed, e.g., on a carrier, and subsequently used to form the assembly 600. As an example, the substrate 650 can be formed by forming a metal layer on a carrier. The metal layer can be patterned and covered with a dielectric layer. One or more vias can be formed through the dielectric layer to connect to the patterned metal layer, and another patterned metal layer can be formed on the dielectric layer. Formation of patterned metal layers, dielectric layers, and vias is repeated until all of the desired features of the substrate 650 are formed, at which point the substrate 650 can be removed from the carrier. Alternatively, operations, such as die attach operations to connect the integrated device 640 to the substrate 650 can be performed before the substrate 650 is removed from the carrier. The substrate 610 can be formed using similar techniques to those described above.

In this example, after formation of the substrates 610, 650, the integrated device 640 can be attached to the substrate 650. Interconnect conductors 662 can also be formed on or attached to the substrate 650. Subsequently, the substrate 610 can be electrically connected to the interconnect conductors 662 and thermally coupled to the integrated device 460. Optionally, a mold compound 606 can be disposed on the substrate 650 after the integrated device 640 is attached to the substrate 650 or can be disposed between the substrates 610, 650 after the substrate 610 is attached. In this example, formation of the assembly 600 is complete after the substrate 610 is attached.

Stage 2 illustrates a state after solder paste, such as a plurality of solder balls or bumps 674, are coupled to the contacts 604, 612, and 616 of the substrate 610. For example, the solder paste can be positioned using pick and place operations.

Stage 3 illustrates a state after redistribution dies 620 and a heat slug 660 are attached (e.g., thermally and/or electrically connected) to the assembly 600. In some implementations, each of the redistribution dies 620 corresponds to an example or instance of the redistribution dies 120 and the heat slug 660 corresponds to an example or instance of the heatsink device 160 of FIGS. 1A-1C. A diagram 676 depicts a top view of the assembly 600 showing placement, on the substrate 610, of four redistribution dies 620A, 620B, 620C, and 620D and the heat slug 660 relative to DDR components 642A, 642B, 642C, and 642D of the integrated device 640.

The diagram 676 also illustrates sets of contacts 613, 615, 617, and 619 (e.g., ball pads) on the surface of the substrate 610. For example, the contacts 613 correspond to a subset of the contacts 612 that are electrically coupled to the redistribution die 620A through routing traces 658, and the contacts 617 correspond to a subset of the contacts 616 that are electrically coupled to the redistribution die 620C through routing traces 658. In some implementations, the sets of contacts 613, 615, 617, and 619 correspond to the third contacts 112C, 114C, 116C, and 118C, respectively, of FIGS. 1A-1C.

In the example illustrated, four redistribution dies 620A, 620B, 620C, and 620D are electrically connected to the substrate 610 via the solder bumps 674. In other examples, more than four or fewer than four redistribution dies 620 may be electrically connected to the substrate 610, such as in a similar manner as depicted in FIG. 4 or FIG. 5 as illustrative, non-limiting examples. Additionally, in the example illustrated, a single heat slug 660 is thermally and, optionally electrically, connected to the substrate 610 via the solder bumps 674. In other examples, more than one heat slug 660 may be thermally and electrically connected to the substrate 610.

Stage 4 of FIG. 6B illustrates a state after placement of the integrated devices 630 and solder reflow. In some implementations, each of the integrated devices 630 (e.g., 630A, 630B) corresponds to an example or instance of the first integrated devices 130 (e.g., the first DRAM device 130A and the second DRAM device 130B, respectively) of FIGS. 1A-1C. A diagram 676 depicts a top view of the assembly 600 showing placement, on the substrate 610, of the integrated devices 630A and 630B relative to the redistribution dies 620A, 620B, 620C, and 620D and the heat slug 660.

In the illustrated example, each of the integrated devices 630 corresponds to a package that includes a die 678 (e.g., a DRAM) that is coupled to a substrate 680 and encapsulated by a protective material 682, such as epoxy plastic. The integrated device 630A includes interconnects 632A that are coupled to the contacts 613, 615 on the substrate 610, and the integrated device 630B includes interconnects 632B that are coupled to contacts 617, 619 on the substrate 610. In some implementations, the interconnects 632A and 632B correspond to the interconnect conductors 132A and 132B, respectively, of FIG. 1A-1C.

Stage 5 illustrates a state after application of an underfill material 684 to an upper surface of the substrate 610.

Stage 6 illustrates a state of the assembly 600 after attachment of one or more optional devices 670 and 686 to the substrate 650 and after formation or attachment of solder balls 654 to the off-package contacts 672. In some implementations, the one or more optional devices 670 and 686 include passive devices. For example, the optional device 670 can correspond to the device 270 of FIG. 2. Although two optional devices 670 and 686 are illustrated, other examples may include any number of such devices or may not include any such devices.

Formation of the device 690 is complete at Stage 6. For example, at Stage 6, the device 690 includes a first substrate (e.g., the substrate 610) that includes a first set of contacts (e.g., the contacts 612). The device 690 also includes a redistribution die (e.g., the redistribution die 620A) coupled to first contacts (e.g., contacts 612 that are coupled to the routing traces 656) of the first set of contacts (e.g., the contacts 612) and to second contacts (e.g., one of each pair of contacts 612 that are coupled to the routing traces 658) of the first set of contacts (e.g., the contacts 612). The redistribution die (e.g., the redistribution die 620A) includes conductors that electrically couple the first contacts (e.g., contacts 612 that are coupled to the routing traces 656) of the first set of contacts (e.g., the contacts 612) to second contacts (e.g., contacts 612 that are coupled to the routing traces 658) of the first set of contacts (e.g., the contacts 612). The device 690 also includes a first integrated device (e.g., the integrated device 630A) coupled to third contacts (e.g., the contacts 613) of the first set of contacts (e.g., the contacts 612), and a second integrated device (e.g., the integrated device 640) coupled to a second substrate (e.g., the substrate 650). The first substrate (e.g., the substrate 610) is disposed between the first integrated device (e.g., the integrated device 630A) and the second integrated device (e.g., the integrated device 640), and the first integrated device (e.g., the integrated device 630A) is electrically coupled to the second integrated device (e.g., the integrated device 640) through the conductors of the redistribution die (e.g., the redistribution die 620A).

### Exemplary Flow Diagram of a Method for Fabricating an Integrated Device Including Redistribution Die(s)

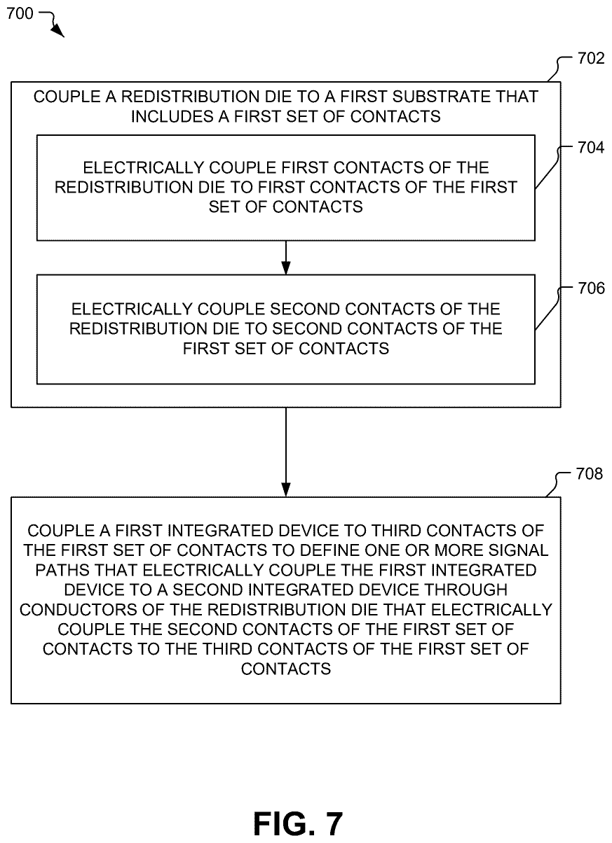

In some implementations, fabricating a device that includes one or more redistribution dies includes several processes. FIG. 7 illustrates an exemplary flow diagram of a method 700 for providing or fabricating an integrated device that includes one or more redistribution dies. In some implementations, the method 700 of FIG. 7 may be used to provide or fabricate any of the devices 100, 200, 300, 400, 500, or 690, of FIGS. 1A-6B.

It should be noted that the method 700 of FIG. 7 may combine one or more processes in order to simplify and/or clarify the method for providing or fabricating a device that includes one or more redistribution dies. In some implementations, the order of the processes may be changed or modified.

The method 700 includes, at block 702, coupling a redistribution die to a first substrate that includes a first set of contacts. For example, the redistribution die can correspond to the redistribution die 120A of any of FIGS. 1A-3, and the first substrate can correspond to the first substrate 110 of any of FIGS. 1A-3. As another example, the redistribution die can correspond to the redistribution die 620A of FIGS. 6A and 6B, and the first substrate can correspond to the substrate 610 of FIGS. 6A and 6B.

Coupling the redistribution die to the first substrate includes electrically coupling first contacts of the redistribution die to first contacts of the first set of contacts, at block 704. For example, the first contacts of the redistribution die can correspond to the contacts 124A of the redistribution die 120A of FIGS. 1A-1C, and the first contacts of the first set of contacts can correspond to the first contacts 112A of the first set of contacts 112 of the first substrate 110 of FIGS. 1A-1C. Coupling the redistribution die to the first substrate also includes electrically coupling second contacts of the redistribution die to second contacts of the first set of contacts, at block 706. For example, the second contacts of the redistribution die can correspond to the contacts 126A of the redistribution die 120A of FIGS. 1A-1C, and the second contacts of the first set of contacts can correspond to the second contacts 112B of the first set of contacts 112 of the first substrate 110 of FIGS. 1A-1C. Operations to electrically connect contacts of a redistribution die to contacts of a substrate are described with reference to Stage 3 of FIG. 6A.

The method 700 also includes, at block 708, coupling a first integrated device to third contacts of the first set of contacts to define one or more signal paths that electrically couple the first integrated device to a second integrated device through conductors of the redistribution die that electrically couple the second contacts of the first set of contacts to the third contacts of the first set of contacts. For example, the first integrated device can correspond to the first DRAM device 130A of FIGS. 1A-1C, the second integrated device can correspond to the second integrated device 140 of FIGS. 1A-1C, the third contacts of the first set of contacts can correspond to the third contacts 112C of FIGS. 1A-1C, and the conductors of the redistribution die can correspond to the conductors 122A of the redistribution die 120A of FIGS. 1A-1C. Operations to couple a first integrated device to contacts of a substrate to electrically couple the first integrated device to a second integrated device through conductors of a redistribution die are described with reference to Stage 4 of FIG. 6B.

In some implementations, the second integrated device is coupled to a second substrate, the first substrate is disposed between the first integrated device and the second integrated device, and the signal paths further include interconnect conductors that electrically couple conductors of the first substrate to conductors of the second substrate. For example, the second integrated device can correspond to the second integrated device 140 of FIGS. 1A-1C, the second substrate can correspond to the second substrate 150 of FIGS. 1A-1C, the first substrate can correspond to the first substrate 110 of FIGS. 1A-1C, and the interconnect conductors can correspond to the interconnect conductors 152 of FIGS. 1A-1C.

In some implementations, the method 700 includes coupling a second redistribution die to the first substrate, where coupling the second redistribution die to the first substrate includes electrically coupling first contacts of the second redistribution die to first contacts of a second set of contacts of the first substrate and electrically coupling second contacts of the second redistribution die to second contacts of the second set of contacts. For example, the second redistribution die can correspond to second redistribution die 120B of FIGS. 1A-1C, the first contacts of the second set of contacts can correspond to the first contacts 114A of the second set of contacts 114 of the first substrate 110 of FIGS. 1A-1C, and the second contacts of the second set of contacts can correspond to the second contacts 114B of the second set of contacts 114 of the first substrate 110 of FIGS. 1A-1C. In such implementations, the method 700 can also include coupling the first integrated device to third contacts of the second set of contacts to define one or more additional signal paths that electrically couple the first integrated device to the second integrated device through conductors of the second redistribution die. For example, with reference to FIGS. 1A-1C, the first DRAM device 130A is coupled to the third contacts 114C of the second set of contacts 114 to electrically couple the first DRAM device 130A of FIGS. 1A-1C to the second integrated device 140 through conductors of the second redistribution die 120B.

In some implementations, the first integrated device includes a first DRAM device, and the method 700 can also include coupling a second DRAM device to the first substrate, where the first DRAM device and the second DRAM device are in a side-by-side configuration on the first substrate. For example, with reference to FIGS. 1A-1C, the first DRAM device 130A and the second DRAM device 130B are coupled to the first substrate 110 and are in a side-by-side configuration on the first substrate 110. Operations to couple a first DRAM device and a second DRAM device to a first substrate in a side-by-side configuration on the first substrate are described with reference to Stages 2 and 3 of FIG. 6A and Stage 4 of FIG. 6B.

In some implementations, the method 700 also includes coupling a heatsink device to the first substrate between the first DRAM device and the second DRAM device. For example, the first heatsink device can correspond to the heatsink device 160 of any of FIGS. 1A-5 or the heat slug 660 of FIGS. 6A and 6B. Operations to couple a heatsink device to a substrate between a first DRAM device and a second DRAM device are described with reference to Stages 2 and 3 of FIG. 6A and Stage 4 of FIG. 6B.

### Exemplary Electronic Devices

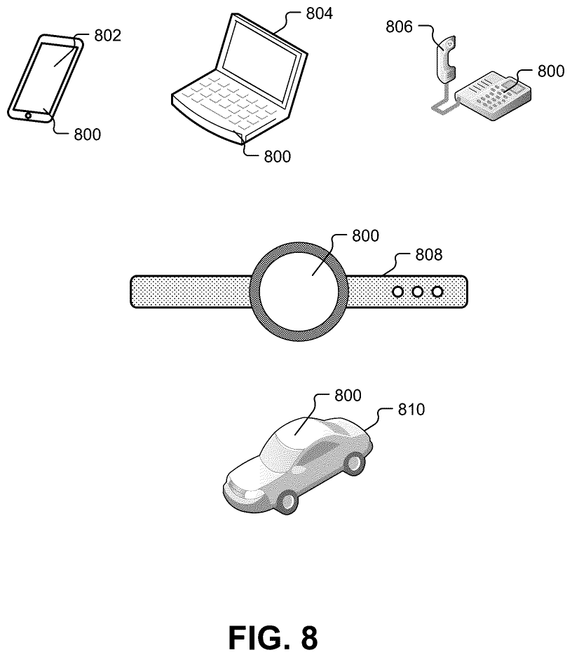

FIG. 8 illustrates various electronic devices that may include or be integrated with any of the devices 100, 200, 300, 400, 500, or 690 of FIGS. 1A-6B. For example, a mobile phone device 802, a laptop computer device 804, a fixed location terminal device 806, a wearable device 808, or a vehicle 810 (e.g., an automobile or an aerial device) may include a device 800. The device 800 can include, for example, any of the devices 100, 200, 300, 400, 500, or 690 of FIGS. 1A-6B described herein. The devices 802, 804, 806 and 808 and the vehicle 810 illustrated in FIG. 8 are merely exemplary. Other electronic devices may also feature the device 800 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1A-8 may be rearranged and/or combined into a single component, process, feature or function or embodied in several components, processes, or functions. Additional elements, components, processes, and/or functions may also be added without departing from the disclosure. It should also be noted FIGS. 1A-8 and its corresponding description in the present disclosure is not limited to dies and/or ICs. In some implementations, FIGS. 1A-8 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes a first substrate that includes a first set of contacts; a redistribution die coupled to first contacts of the first set of contacts and to second contacts of the first set of contacts, wherein the redistribution die includes conductors that electrically couple the first contacts of the first set of contacts to the second contacts of the first set of contacts; a first integrated device coupled to third contacts of the first set of contacts; and a second integrated device coupled to a second substrate, wherein the first substrate is disposed between the first integrated device and the second integrated device, and the first integrated device is electrically coupled to the second integrated device through the conductors of the redistribution die.

Example 2 includes the device of Example 1, wherein the redistribution die is at least partially disposed within a shadow of the first integrated device.

Example 3 includes the device of Example 1 or Example 2, wherein the redistribution die is at least partially within a ball standoff space of the first integrated device.

Example 4 includes the device of any of Examples 1 to 3, wherein the first integrated device includes a first dynamic random access memory (DRAM) device.

Example 5 includes the device of Example 4, wherein the first substrate includes first contacts of a second set of contacts, second contacts of the second set of contacts, and third contacts of the second set of contacts, and wherein the first DRAM device is further coupled to the third contacts of the second set of contacts.

Example 6 includes the device of Example 5, wherein the redistribution die is between the third contacts of the first set of contacts and the third contacts of the second set of contacts.

Example 7 includes the device of Example 6, wherein the third contacts of the first set of contacts and the third contacts of the second set of contacts are arranged according to a JEDEC DRAM pinmap.

Example 8 includes the device of Example 6 or Example 7, and further includes a second redistribution die coupled to the first contacts of the second set of contacts and to the second contacts of the second set of contacts, wherein the second redistribution die includes conductors that electrically couple the first contacts of the second set of contacts to the second contacts of the second set of contacts.

Example 9 includes the device of any of Examples 5 to 8, and further includes a second DRAM device coupled to the first substrate, wherein the first DRAM device and the second DRAM device are in a side-by-side configuration on the first substrate.

Example 10 includes the device of Example 9, and further includes a heatsink device coupled to the first substrate and positioned between the first DRAM device and the second DRAM device.

Example 11 includes the device of Example 9 or Example 10, wherein the first substrate further includes a third set of contacts and a fourth set of contacts, and wherein the second DRAM device is coupled to third contacts of the third set of contacts and to third contacts of the fourth set of contacts. The device further includes a third redistribution die coupled to first contacts of the third set of contacts and to second contacts of the third set of contacts, wherein the third redistribution die includes conductors that electrically couple the first contacts of the third set of contacts to the second contacts of the third set of contacts. The device also includes a fourth redistribution die coupled to first contacts of the fourth set of contacts and to second contacts of the fourth set of contacts, wherein the fourth redistribution die includes conductors that electrically couple the first contacts of the fourth set of contacts to the second contacts of the fourth set of contacts.

Example 12 includes the device of any of Examples 1 to 11, wherein the redistribution die comprises at least one deep trench capacitor coupled to a power distribution network of the first integrated device through one or more of the third contacts of the first set of contacts.

According to Example 13, a method of fabricating an integrated device includes coupling a redistribution die to a first substrate that includes a first set of contacts, wherein coupling the redistribution die to the first substrate includes: electrically coupling first contacts of the redistribution die to first contacts of the first set of contacts; and electrically coupling second contacts of the redistribution die to second contacts of the first set of contacts. The method also includes coupling a first integrated device to third contacts of the first set of contacts to define one or more signal paths that electrically couple the first integrated device to a second integrated device through conductors of the redistribution die that electrically couple the second contacts of the first set of contacts to the third contacts of the first set of contacts.

Example 14 includes the method of Example 13, wherein the second integrated device is coupled to a second substrate, wherein the first substrate is disposed between the first integrated device and the second integrated device, and wherein the signal paths further include interconnect conductors that electrically couple conductors of the first substrate to conductors of the second substrate.

Example 15 includes the method of Example 13 or Example 14, and further includes coupling a second redistribution die to the first substrate, wherein coupling the second redistribution die to the first substrate includes: electrically coupling first contacts of the second redistribution die to first contacts of a second set of contacts of the first substrate; and electrically coupling second contacts of the second redistribution die to second contacts of the second set of contacts. The method also includes coupling the first integrated device to third contacts of the second set of contacts to define one or more additional signal paths that electrically couple the first integrated device to the second integrated device through conductors of the second redistribution die.

Example 16 includes the method of any of Examples 13 to 15, wherein the first integrated device includes a first dynamic random access memory (DRAM) device, and the method further includes coupling a second DRAM device to the first substrate, wherein the first DRAM device and the second DRAM device are in a side-by-side configuration on the first substrate.

Example 17 includes the method of Example 16, and further includes coupling a heatsink device to the first substrate between the first DRAM device and the second DRAM device.

According to Example 18, a device includes a first substrate that includes a first set of contacts and a second set of contacts. The device includes a first redistribution die coupled to first contacts of the first set of contacts and to second contacts of the first set of contacts, wherein the first redistribution die includes conductors that electrically couple the first contacts of the first set of contacts to the second contacts of the first set of contacts. The device includes a second redistribution die coupled to first contacts of the second set of contacts and to second contacts of the second set of contacts, wherein the second redistribution die includes conductors that electrically couple the first contacts of the second set of contacts to the second contacts of the second set of contacts. The device also includes a first dynamic random access memory (DRAM) device coupled to third contacts of the first set of contacts and to third contacts of the second set of contacts; and a system-on-chip (SOC) device coupled to a second substrate, wherein the first substrate is disposed between the first DRAM device and the SOC device, and the first DRAM device is electrically coupled to the SOC device through the conductors of the first redistribution die and the second redistribution die.

Example 19 includes the device of Example 18, and further includes a second DRAM device coupled to the first substrate, wherein the first DRAM device and the second DRAM device are in a side-by-side configuration on the first substrate.

Example 20 includes the device of Example 19, and further includes a heatsink device coupled to the first substrate and positioned between the first DRAM device and the second DRAM device.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A device comprising:
a first substrate that includes a first set of contacts;
a redistribution die coupled to first contacts of the first set of contacts and to second contacts of the first set of contacts, wherein the redistribution die includes conductors that electrically couple the first contacts of the first set of contacts to the second contacts of the first set of contacts;
a first integrated device coupled to third contacts of the first set of contacts; and
a second integrated device coupled to a second substrate, wherein the first substrate is disposed between the first integrated device and the second integrated device, and the first integrated device is electrically coupled to the second integrated device through the conductors of the redistribution die.

2. The device of claim 1, wherein the redistribution die is at least partially disposed within a shadow of the first integrated device.

3. The device of claim 1, wherein the redistribution die is at least partially within a ball standoff space of the first integrated device.

4. The device of claim 1, wherein the first integrated device includes a first dynamic random access memory (DRAM) device.

5. The device of claim 4, wherein the first substrate includes first contacts of a second set of contacts, second contacts of the second set of contacts, and third contacts of the second set of contacts, and wherein the first DRAM device is further coupled to the third contacts of the second set of contacts.

6. The device of claim 5, wherein the redistribution die is between the third contacts of the first set of contacts and the third contacts of the second set of contacts.

7. The device of claim 6, wherein the third contacts of the first set of contacts and the third contacts of the second set of contacts are arranged according to a JEDEC DRAM pinmap.

8. The device of claim 6, further comprising a second redistribution die coupled to the first contacts of the second set of contacts and to the second contacts of the second set of contacts, wherein the second redistribution die includes conductors that electrically couple the first contacts of the second set of contacts to the second contacts of the second set of contacts.

9. The device of claim 5, further comprising a second DRAM device coupled to the first substrate, wherein the first DRAM device and the second DRAM device are in a side-by-side configuration on the first substrate.

10. The device of claim 9, further comprising a heatsink device coupled to the first substrate and positioned between the first DRAM device and the second DRAM device.

11. The device of claim 9, wherein the first substrate further includes a third set of contacts and a fourth set of contacts, wherein the second DRAM device is coupled to third contacts of the third set of contacts and to third contacts of the fourth set of contacts, and further comprising:
a third redistribution die coupled to first contacts of the third set of contacts and to second contacts of the third set of contacts, wherein the third redistribution die includes conductors that electrically couple the first contacts of the third set of contacts to the second contacts of the third set of contacts; and
a fourth redistribution die coupled to first contacts of the fourth set of contacts and to second contacts of the fourth set of contacts, wherein the fourth redistribution die includes conductors that electrically couple the first contacts of the fourth set of contacts to the second contacts of the fourth set of contacts.

12. The device of claim 1, wherein the redistribution die comprises at least one deep trench capacitor coupled to a power distribution network of the first integrated device through one or more of the third contacts of the first set of contacts.

13. A method of fabricating an integrated device, the method comprising:
coupling a redistribution die to a first substrate that includes a first set of contacts, wherein coupling the redistribution die to the first substrate includes:
electrically coupling first contacts of the redistribution die to first contacts of the first set of contacts; and
electrically coupling second contacts of the redistribution die to second contacts of the first set of contacts; and
coupling a first integrated device to third contacts of the first set of contacts to electrically couple the first integrated device to a second integrated device through conductors of the redistribution die to define one or more signal paths that electrically couple the second contacts of the first set of contacts to the third contacts of the first set of contacts.

14. The method of claim 13, wherein the second integrated device is coupled to a second substrate, wherein the first substrate is disposed between the first integrated device and the second integrated device, and wherein the signal paths further include interconnect conductors that electrically couple conductors of the first substrate to conductors of the second substrate.

15. The method of claim 13, further comprising:
coupling a second redistribution die to the first substrate, wherein coupling the second redistribution die to the first substrate includes:
electrically coupling first contacts of the second redistribution die to first contacts of a second set of contacts of the first substrate; and
electrically coupling second contacts of the second redistribution die to second contacts of the second set of contacts; and
coupling the first integrated device to third contacts of the second set of contacts to define one or more additional signal paths that electrically couple the first integrated device to the second integrated device through conductors of the second redistribution die.

16. The method of claim 13, wherein the first integrated device includes a first dynamic random access memory (DRAM) device, and further comprising:
coupling a second DRAM device to the first substrate, wherein the first DRAM device and the second DRAM device are in a side-by-side configuration on the first substrate.

17. The method of claim 16, further comprising coupling a heatsink device to the first substrate between the first DRAM device and the second DRAM device.

18. A device comprising:
a first substrate that includes a first set of contacts and a second set of contacts;
a first redistribution die coupled to first contacts of the first set of contacts and to second contacts of the first set of contacts, wherein the first redistribution die includes conductors that electrically couple the first contacts of the first set of contacts to the second contacts of the first set of contacts;
a second redistribution die coupled to first contacts of the second set of contacts and to second contacts of the second set of contacts, wherein the second redistribution die includes conductors that electrically couple the first contacts of the second set of contacts to the second contacts of the second set of contacts;
a first dynamic random access memory (DRAM) device coupled to third contacts of the first set of contacts and to third contacts of the second set of contacts; and
a system-on-chip (SOC) device coupled to a second substrate, wherein the first substrate is disposed between the first DRAM device and the SOC device, and the first DRAM device is electrically coupled to the SOC device through the conductors of the first redistribution die and the second redistribution die.

19. The device of claim 18, further comprising a second DRAM device coupled to the first substrate, wherein the first DRAM device and the second DRAM device are in a side-by-side configuration on the first substrate.

20. The device of claim 19, further comprising a heatsink device coupled to the first substrate and positioned between the first DRAM device and the second DRAM device.
